(19) United States
(12) Patent Application Publication
(10) Pub. No.: US 2008/0070406 A1
(43) Pub. Date: Mar. 20, 2008

(54) PATTERN FORMING METHOD AND SEMICONDUCTOR DEVICE MANUFACTURING METHOD USING THE SAME

(75) Inventor: Fumihiro KOBA, Kanagawa (JP)

Correspondence Address: YOUNG & THOMPSON, 745 SOUTH 23RD STREET, 2ND FLOOR, ARLINGTON, VA, 22202, US

(73) Assignee: NEC ELECTRONICS CORPORATION, Kanagawa (JP)

(21) Appl. No.: 11/853,847

(22) Filed: Sep. 12, 2007

(30) Foreign Application Priority Data
Sep. 14, 2006 (JP) 2006-250023

(51) Int. Cl. H01L 21/44

(52) U.S. Cl. 438/669; 257/E21.476

(57) ABSTRACT

A resist film is formed on a substrate. A conductive layer is formed on the resist film. The resist film is exposed to an electron beam. The conductive layer is removed by a remover whose temperature is equal to or higher than 30° C. and equal to or lower than 35° C. The resist film is developed to form a predetermined pattern. Therefore, the conductive layer can be removed without leaving a removal residue, so the pattern after developing is formed at high uniformity within wafer.

### BACKGROUND OF THE INVENTION

1. Field of the Invention

The present invention relates to a pattern forming method using resist, and more particularly, a pattern forming method for improving uniformity within wafer after resist development.

2. Description of the Related Art

In recent years, electron beam (EB) exposure is used accompanying with a size reduction of a semiconductor element. According to the EB exposure, concave and convex alignment marks on a substrate are scanned with an electron beam and electrons reflected thereon are detected to realize high-precision alignment. For example, in the case of the EB exposure, an electron beam is emitted to a chemically amplified resist formed on a substrate and an integrated circuit pattern is formed.

There is a conventional resist developing method disclosed in, for example, JP 2003-197508 A. The method disclosed in JP 2003-197508 A is a developing method of a typical photolithography. Developer is supplied to a substrate at a constant temperature to shorten a developing time.

JP 2006-032604 A discloses a flow for performing baking after the electron beam exposure and then performing cooling, removal of a surface modification layer, and developing. According to JP 2006-032604 A, a surface modification liquid for promoting an acid catalytic reaction is applied onto a resist film and the surface modification layer is removed by a remover after exposure.

JP 2000-124120A discloses a method for improving uniformity within wafer in which the temperature of resist or developer is precisely controlled by placing a wafer on a temperature controlled holder.

However, the inventor of this application found the following problem. A remover is used to remove a conductive layer formed on a resist film after the EB exposure. The resist and the developer are temperature-controlled in a conventional technique, but residue is caused after conductive layer is removed. The residue causes a deterioration of uniformity within wafer after developing. In a conventional case, the temperatures of the resist and the developer are adjusted but a temperature of the remover of the conductive layer is not taken into account.

### SUMMARY

As a result of intensive studies for solving the above-mentioned problem, the inventor of this application found that, when the conductive layer formed on the resist film is removed by the remover whose temperature is appropriately controlled, the residue of the conductive layer is prevented. Therefore, the present invention has been completed.

According to the present invention, there is provided a pattern forming method including the steps of: forming a resist film on a substrate; forming a conductive layer on the resist film; exposing the resist film to an electron beam; removing the conductive layer by a remover whose temperature is equal to or higher than 30° C. and equal to or lower than 35° C.; and developing the resist film to form a predetermined pattern.

In a conventional case, the temperatures of the resist and the developer are controlled to avoid some influence for patterning process from heating or absorption caused by reaction between the resist and the developer. However, there is no case where the temperature control is performed during the process for removing the conductive layer in view of prevention of the residue of the conductive layer. In contrast to this, the inventor of the present invention found that, when the temperature of the remover is controlled appropriately, the residue of the conductive layer is prevented, thereby solving the above-mentioned problem. The present invention has been made based on such a novel finding that controlling the temperature of the remover of the conductive layer improved to reduce the residue of the conductive layer, thereby improving the uniformity within wafer at the time of developing.

In the step of removing the conductive layer, the remover may be supplied onto the conductive layer at the temperature equal to or higher than 30° C. and equal to or lower than 35° C. for a period of time equal to or longer than 20 seconds and equal to or shorter than 40 seconds.

Further, the resist film includes, for example, a chemically amplified resist film.

Still further, the step of removing the conductive layer may include: a first removal step of removing the conductive layer by a remover at a temperature; and a second removal step of removing a residue of the conductive layer by the remover whose temperature is equal to or higher than 30° C. and equal to or lower than 35° C., the temperature of the remover in the first removal step being lower than the temperature of the remover in the second removal step. In the first removal step, the remover may be supplied, for example, at the temperature equal to or higher than 20° C. and equal to or lower than 25° C. for a period of time equal to or longer than 20 seconds and equal to or shorter than 40 seconds.

Yet further, in the second removal step, the remover may be supplied at the temperature equal to or higher than 30° C. and equal to or lower than 35° C. for a period of time equal to or longer than 20 seconds and equal to or shorter than 40 seconds.

Further, according to the present invention, there is provided a method of manufacturing a semiconductor device including: forming a film on a semiconductor substrate; forming a resist film having a predetermined pattern on the film; and etching the film using the resist film as a mask, in which the step of forming the resist film includes the steps of: forming the resist film on the substrate; forming a conductive layer on the resist film; exposing the resist film to an electron beam; removing the conductive layer by a remover whose temperature is equal to or higher than 30° C. and equal to or lower than 35° C.; and developing the resist film to obtain the predetermined pattern.

### BRIEF DESCRIPTION OF THE DRAWING

The above and other objects, advantages and features of the present invention will be more apparent from the following description taken in conjunction with the accompanying drawings, in which:

FIG. 1 is a process diagram illustrates an example of an electron beam (EB) lithography process.

### DETAILED DESCRIPTION OF PREFERRED EMBODIMENT

The invention will be now described herein with reference to illustrative embodiments. Those skilled in the art will recognize that many alternative embodiments can be accomplished using the teachings of the present invention and that the invention is not limited to the embodiments illustrated for explanatory purposes.

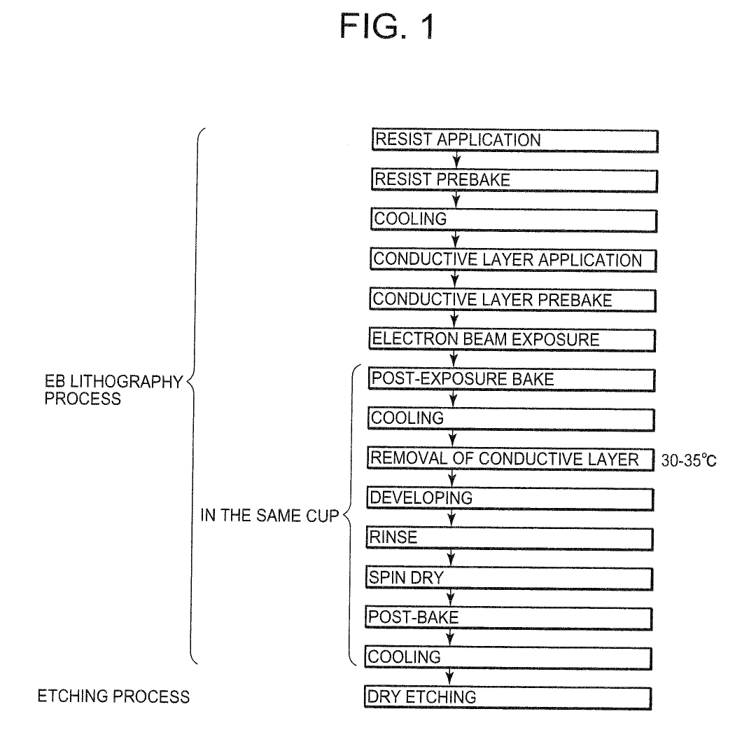

Hereinafter, an outline of a pattern forming method according to an embodiment of the present invention will be described. FIG. 1 illustrates an example of an electron beam lithography process.

The pattern forming method according to this embodiment includes a step of forming a resist film on a substrate, a step of forming a conductive layer on the resist film, a step of exposing the resist film to an electron beam, a step of removing the conductive layer by using a remover whose temperature is equal to or higher than 30° C. and equal to or lower than 35° C., and a step of developing the resist film to form a predetermined pattern.

Hereinafter, the pattern forming method according to this embodiment will be described in detail.

First, a film is formed on or over a silicon substrate which is a semiconductor substrate by using a typical procedure. The procedure is not particularly limited thereto. The film is formed by, for example, a CVD method. The formed film is, for example, an inorganic film containing Si and O as constituent elements. Examples of the inorganic film include an SiOC film, an SiON film, and an SiO₂ film.

Subsequently, the resist film is formed on the film.

A resist to be used is, for example, a chemically amplified resist. The chemically amplified resist contains an acid generator which generates an acid when irradiated with light or an electron beam and a compound which reacts by an acid. A resist pattern is formed by a change in alkali dissolution characteristic of the compound which is caused by an acid catalytic reaction. The acid generator is selected from well known materials based on energies of a light source and an electron beam source which are used for irradiation. A material transparent to a wavelength of each of the light source or the electron beam source is used as a basic resin. A material having a side chain susceptible to acid hydrolysis is used as the basic resin at a side chain thereof, so a solubility difference to a developer before and after exposure can be sufficiently ensured. A well known material generally employed for the chemically amplified resist is used appropriately as the basic resin. For example, in the case of a positive type resist composition, it is possible to use a basic resin which is an alkali insoluble or refractory resin having an acid functional group protected by an alkali soluble group and becomes alkali soluble when the alkali soluble group is released. In the case of a negative type resist composition, it is possible to use a basic resin which is an alkali soluble resin and becomes alkali refractory by crosslinking using a crosslinking agent. In this embodiment, it is particularly preferable to use, as the resist, a calixarene which is a negative type chemically amplified resist.

The chemically amplified resist in which the acid generator and the basic resin are dissolved in an organic solvent is applied onto the layer located on the semiconductor substrate. The chemically amplified resist contains an appropriately material such as a quencher. Therefore, the sensitivity in lithography more certainly could be improved. When the chemically amplified resist is positive type, a dissolution inhibitor may be contained therein. When the chemically amplified resist is negative type, a crosslinking agent may be contained therein. The resist contains the acid generator therein, for example, a diazodisulfone acid generator or a triphenylsulfonium acid generator.

A conductive film for antistatic purpose (conductive layer) is formed on the resist film. The conductive layer contains, for example, a conductive polymer (approximately 5%), water (approximately 95%), and a surface-active agent. The surface of the resist is usually water-repellent. In contrast to this, a major part of the conductive layer is water, so a surface-active agent may be used for easily performing an application onto the resist. In order to improve an application property of the conductive layer onto the resist, a small amount of ethanol may be added.

Examples of the conductive polymer to be used include a polymer whose main chain has a conjugate double bond, such as a polyaniline polymer, and a polyaniline sulfone polymer.

Next, the resist film is subjected to electron beam exposure. Then, post-exposure bake (PEB) is performed at a temperature of 100° C. to 130° C. and cooling is performed. A hot plate temperature for cooling is preferably set to, for example, a temperature equal to or higher than 30° C. and equal to or lower than 35° C. in view of the temperature of the remover in a subsequent removal process.

In this embodiment, the conductive layer is removed in the same developing cup by the remover whose temperature is equal to or higher than 30° C. and equal to or lower than 35° C.

When the temperature of the remover is too low, the conductive layer cannot be sufficiently removed, so the residue of the conductive layer is partially caused on the substrate. Therefore, there may be a region including no residue of the conductive layer and a region including a residue thereof on the resist which results in disturbing the developing. As a result, it is likely to reduce a developing speed of the region including the residue, thereby causing unevenness in developing of the resist.

On the other hand, when the temperature of the remover is too high, it is likely to influence the stable supply of the remover. That is, even when a temperature adjustment can be performed between a pipe lines for supplying the remover to a tip of a nozzle for dropping the remover on the substrate, it is difficult to maintain the remover at high temperature. When the remover whose temperature is too high is supplied onto the substrate, temperature decrease on the substrate is likely to occur. The degree of the temperature decrease becomes larger as the temperature of the remover increases. Therefore, the temperature distribution on the substrate becomes non-uniform to cause residue. When the resist to which the conductive layer is applied is immersed in the remover whose temperature is high, it is likely to react the acid of the conductive layer with the acid generator of the resist, thereby producing a reactant which is not removed. This leads to residual of the remover.

The remover is supplied on the conductive layer for approximately 20 to 40 seconds. The conductive layer is removed successfully for such a period of time and simultaneously the mixing between the resist and the conductive layer can be prevented.

The removing process can be done by a dip process, single wafer process, or the like. In the dip process, a plurality of wafers is immersed in a treatment bath. This process has an advantage that the plurality of wafers can be treated at the same time. However, the plurality of wafers are arranged in a line and immersed for treatment in a treatment solution, so there is some possibility that contaminants removed from a surface of a wafer are dissolved or dispersed in the solution and then deposited to a rear surface of another adjacent wafer again. On the other hand, using the single wafer process, treatment is performed for each wafer. That is, a wafer is laterally held on a holding base and a treatment liquid is sprayed to a surface of the wafer while the wafer is rotated within a wafer plane. According to this process, a contamination problem does not occur from another wafer, so the cleaning process can be performed effectively.

The remover may be supplied by using another method such as spraying the remover onto the conductive layer.

Here, a plurality of steps may be included in the removal process. In this embodiment, a process including:

(i) a first removal step of removing the conductive layer by using a remover at a temperature; and

(ii) a second removal step of removing the residue by using the remover whose temperature is equal to or higher than 30° C. and equal to or lower than 35° C. is employed.

The temperature of a remover used in the first removal step is lower than the temperature of the remover used in the second removal step.

In this embodiment, the temperature of the remover used in the first removal step is, for example, equal to or higher than 20° C. and equal to or lower than 25° C. However, the temperature of the remover used in the first removal step is desirably lower than the temperature of the remover used in the second removal step and thus not limited within the temperature range. The remover is supplied on the conductive film for approximately 20 to 40 seconds. According to this step, most part of the conductive layer is removed.

In this embodiment, the temperature of the remover used in the second removal step is equal to or higher than 30° C. and equal to or lower than 35° C. The remover is supplied on the conductive film for approximately 20 to 40 seconds. In this step, the residue of the conductive layer which cannot be completely removed in the first removal step is removed.

When a mixing occurs between the resist and the conductive layer, it is preferable to remove the residue by the remover whose temperature is equal to or higher than 30° C. and equal to or lower than 35° C. after the removal is performed at low temperature temporarily. For example a polymer component such as a polyaniline sulfone polymer which is components of the conductive layer indicates acid. Therefore, there is a possibility that an acid generator of the chemically amplified resists reacts with the polymer component, thereby producing a reactant which is not removed. When the temperature control during the removal is divided into two steps, such an inconvenience can be avoided.

In some combinations of the resist and the conductive layer, the conductive layer cannot be completely removed by the single step of supplying the remover whose temperature is equal to or higher than 30° C. and equal to or lower than 35° C. for approximately 20 to 40 seconds. In such a case, it is necessary to extend a rinse time of the remover. However, when the rinse time is too long, it is likely to cause the mixing between the resist and the conductive layer. Therefore, the removal step is divided into a plurality of steps performed at different temperatures, so the removal of the conductive layer can be effectively achieved without lengthening a remover supply time at high temperature.

In this embodiment, when the step of removing the conductive layer is completed, the resist is subsequently developed in the same cup by using the developer. A developer temperature is, for example, 23° C. to 35° C. When the developer temperature is high, resist will dissolve rapidly. Therefore, high-temperature developing is preferable in view of improving through-put. On the other hand, when the temperature is too high, temperature control becomes difficult. Thus, the developer temperature is preferably within the above-mentioned range.

After developing, while the substrate is rotated, deionized water rinse is performed for several tens of seconds. After the completion of the deionized water rinse, spin dry is performed while the substrate continues to be rotated. The temperature of supplying the deionized water used for rinsing will keep the same temperature as the temperature of supplying remover or developer, in view of those processes using same cup of an apparatus. Therefore, a preferable temperature of the deionized water is equal to or higher than 30° C. and equal to or lower than 35° C.

After developing, the shape and size of the resist pattern on the substrate are checked. Then the substrate is etched using the resist pattern as a mask to form a desirable pattern.

The present invention can be also applied to a semiconductor device manufacturing method by using above explained pattern formation method.

The semiconductor device manufacturing method according to the embodiment of the present invention includes, for example, a step of forming a film on a semiconductor substrate, a step of forming a resist film having a predetermined pattern on the film, and a step of performing etching of the resist film as a mask.

The step of forming the resist film includes the following:

a step of forming the resist film on the semiconductor substrate;

a step of forming a conductive layer on the resist film;

a step of exposing the resist film to an electron beam;

a step of removing the conductive layer by using a remover whose temperature is equal to or higher than 30° C. and equal to or lower than 35° C.; and

a step of developing the resist film to obtain a predetermined pattern.

In the above, the embodiment of the present invention is described. The embodiment is an example of the present invention and thus various methods other than the above-mentioned methods can be employed.

For example, a third removal step may be included in the step of removing the conductive layer. A suitable method is selected as appropriate based on a combination of the resist and the conductive layer.

### EXAMPLES

Next, examples of the present invention will be described.

### Example 1

The pattern formation is performed by the same method as that in the above-mentioned embodiment.

Calixarene which is the negative type chemically amplified resist was used as the resist for the EB lithography. The resist film was formed on an antireflection film which was formed over the silicon substrate and then prebake was performed at approximately 90° C. for 90 seconds. After that, the conductive layer was formed on the resist film. The conductive layer used was a conductive layer (aquaSAVE-57xs) produced by Mitsubishi Rayon Co., Ltd. The layer thickness of the conductive layer was set to 30 nm. The prebake was performed at 80° C. for 60 seconds. After the prebake of the conductive layer, the stacked films were subjected to electron beam exposure. Then, the conductive layer was removed in the same developing cup by supplying deionized water for 30 seconds which was used as the remover and had a temperature of 35° C. Subsequently, the pattern was developed in the same cup by using a tetramethylammonium hydroxide (TMAH) liquid as the remover.

In this example, after the step of removing the conductive layer, the residue was not observed. The pattern size uniformity within wafer deviation σ3 after developing was 5.1 nm.

### Example 2

The pattern formation was performed by the same procedure as that in Example 1, except for the condition under which the temperature of the remover was set to 30° C.

In this example, after the step of removing the conductive layer, the residue was not observed. The pattern size uniformity within wafer deviation σ3 after developing was 5.1 nm.

### Comparative Example 1

The pattern formation was performed by the same procedure as that in Example 1, except for the condition in which the temperature of the remover was set to 23° C.

In this comparative example, after the step of removing the conductive layer, some residue was observed. The pattern size uniformity within wafer deviation σ3 after developing was 5.5 nm.

### Example 3

A positive type chemically amplified resist (application film thickness is 350 nm) was applied over the semiconductor substrate and prebaked (at 120° C. for 90 seconds). After that, the conductive layer (aquaSAVE-57xs produced by Mitsubishi Rayon Co., Ltd, 30 nm in layer thickness) was applied onto the resist and prebaked (at 80° C. for 60 seconds). The stacked films were subjected to electron beam exposure. The resist with the conductive layer was post-baked (at 110° C. for 90 seconds). When deionized water (23° C.) was supplied for 30 seconds while the wafer was rotated in the developing cup, the conductive layer was roughly removed. Subsequently, when deionized water (35° C.) was supplied for 30 seconds, the conductive layer was completely removed. After the supply of the deionized water was stopped, the wafer was rotated for 20 seconds to blow the deionized water on the wafer (spin dry). The wafer continued to be rotated and a developer was dropped thereon to develop the resist.

In this example, after the step of removing the conductive layer, any residue was not observed. The same preferable result as that in Example 1 was obtained as the pattern size uniformity within wafer after developing.

There is no residue after removing the conductor layer and the size uniformity within wafer of contact hole (1:1) patterns of 70 nm within a 300 nm wafer is low deviation value in case of embodiment example as described above.

The amount of residue of the conductor layer is reduced by using the predetermined removal temperature, therefore the uniformity within wafer was improved.

What is claimed is:

1. A pattern forming method, comprising:
forming a resist film on a substrate;
forming a conductive layer on the resist film;
exposing the resist film to an electron beam;
removing the conductive layer by a remover whose temperature is equal to or higher than 30° C. and equal to or lower than 35° C.; and
developing the resist film.

2. A pattern forming method according to claim 1, wherein the remover is supplied onto the conductive layer for a period of time equal to or longer than 20 seconds and equal to or shorter than 40 seconds.

3. A pattern forming method according to claim 1, wherein the resist film comprises a chemically amplified resist film.

4. A pattern forming method according to claim 1, wherein:
removing the conductive layer comprises,
a first removal step of removing the conductive layer by a remover at a temperature and
a second removal step of removing a residue of the conductive layer by the remover whose temperature is equal to or higher than 30° C. and equal to or lower than 35° C.; and
the temperature of the remover in the first removal step is lower than the temperature of the remover in the second removal step.

5. A pattern forming method according to claim 4, wherein, in the first removal step, the remover is supplied at the temperature equal to or higher than 20° C. and equal to or lower than 25° C. for a period of time equal to or longer than 20 seconds and equal to or shorter than 40 seconds.

6. A pattern forming method according to claim 4, wherein, in the second removal step, the remover is supplied for a period of time equal to or longer than 20 seconds and equal to or shorter than 40 seconds.

7. A method of manufacturing a semiconductor device, comprising the steps of:
forming a film on a substrate;
forming a resist film having a predetermined pattern on the film; and
etching the film using the resist film as a mask,
wherein the step of forming the resist film includes the steps of:
forming the resist film on the substrate;
forming a conductive layer on the resist film;
exposing the resist film to an electron beam;
removing the conductive layer by a remover whose temperature is equal to or higher than 30° C. and equal to or lower than 35° C.; and
developing the resist film to obtain the predetermined pattern.

8. A method comprising:
forming a resist film on a substrate;
forming a conductive layer on the resist film;
exposing the resist film to an electron beam;
removing the conductive layer; and
developing the resist film;
wherein the removing the conductive layer includes subjecting the conductive layer to a remover having a temperature in a range of 30° C. to 35° C.

9. The method as claimed in claim 8 further includes subjecting the conductive layer to another remover having a temperature in a range of 20° C. to 25° C.
